(19) United States
(12) Patent Application Publication
(10) Pub. No.: US 2025/0331339 A1
(43) Pub. Date: Oct. 23, 2025

(54) NARROW STRIPE-SHAPED EDGE-EMITTING MICRO-LED

(71) Applicant: THYSTAR TECHNOLOGY CORPORATION, Hsinchu (TW)

(72) Inventor: WU-SHENG CHI, Hsinchu (TW)

(21) Appl. No.: 18/966,474

(22) Filed: Dec. 3, 2024

Related U.S. Application Data
(60) Provisional application No. 63/635,114, filed on Apr. 17, 2024.

(51) Int. Cl. H10H 20/855; H10H 20/824; H10H 20/841

(52) U.S. Cl. CPC H10H 20/855; H10H 20/841; H10H 20/824

(57) ABSTRACT

The present invention relates to a narrow strip-shaped edge-emitting micro-LED. The LED features an active layer designed as a narrow strip-shaped structure, surrounded by a material layer with a refractive index smaller than that of the active layer to form an optical waveguide. This waveguide confines the propagation direction of light, ensuring that emission occurs predominantly at the two ends of the narrow strip-shaped active layer. Additionally, the material layer with the smaller refractive index may be covered by a reflective layer to further enhance light confinement within the optical waveguide. This design provides excellent light confinement, resulting in high radiation intensity, a small beam divergence angle, and reduced optical loss when coupled to a transmission medium. These characteristics enable the micro-LED to offer significant advantages in miniaturization, thinness and cost reduction for parallel optical link modules.

### CROSS-REFERENCE TO RELATED APPLICATIONS

This application claims priority to US Provisional Application Ser. No. 63/635,114, filed Apr. 17, 2024, which is herein incorporated by reference in its entirety.

### BACKGROUND

### Technical Field

The present invention relates to a narrow strip-shaped edge-emitting micro-LED suitable for use in parallel optical links. The narrow beam divergence angle of the narrow strip-shaped edge-emitting micro-LED, combined with its light-emitting direction parallel to an optical transmission medium (such as an optical fiber or an optical waveguide), enables easy alignment between the light source and the optical fiber or waveguide. This configuration minimizes optical coupling losses, thereby contributing to the miniaturization, reduced thickness, and cost-effectiveness of parallel optical link modules.

### Related Art

Optical link technology plays a crucial role in field requiring high-speed computing. Unlike traditional electronic signal transmission, which relies on electrons traveling through copper wires on conventional circuit board, optical link technology utilizes photons to transmit signals. As photons move faster than electrons and generate significantly less heat, this technology offers superior transmission performance, making it an essential advancement for high-speed data processing and communication systems.

Fiber communication systems have predominantly used laser diodes as light sources to emit optical signals. While laser diodes combined with optical modulators can transmit optical signals at high data rates, their production processes are complex and expensive. Furthermore, the performance of laser diode is highly sensitive to temperature variations, and optical transceivers incorporating laser diodes as light sources are too large, making them unsuitable for efficient integration and packaging with silicon integrated circuit chips.

Pezeshki presented a technology for chip-to-chip optical signal transmission using a micro-LED in an integrated circuit at the CS MANTECH Conference (May 9-12, 2022). With this type of micro-LED, the reduction in component size led to a corresponding decrease in the capacitance effect. Consequently, the RC time constant of the micro-LED was significantly reduced, resulting in an improved modulation bandwidth and data rate. However, this micro-LED was a surface-emitting LED, which had a wide light-emitting angle. This resulted in low efficiency when coupling light into an optical fiber. Furthermore, as the size of the micro-LED decreased, more light was emitted from its four sides than from its surface, making it less suitable for efficient light coupling into optical fibers. Additionally, the direction of light emitted by the surface-emitting micro-LED was perpendicular to the optical transmission medium (such as an optical fiber or optical waveguide). This necessitated the use of a 45-degree reflector to redirect the light by 90 degrees, thereby complicating the production process.

### SUMMARY

In view of the aforementioned conventional issues, an object of the present invention is to design the active layer of an edge-emitting micro-LED into a narrow strip structure to form an optical waveguide structure with enhanced light confinement. As a result, the invention achieves high radiation intensity, a reduced beam divergence angle, and minimized light loss when coupling light into transmission media such as optical fibers or optical waveguides.

Another object of the present invention is to ensure that the light-exiting direction is parallel to the optical transmission medium. This facilitates alignment between the light source and the optical fiber or the optical waveguide, resulting in minimal coupling light loss. Additionally, this design offers advantages in the miniaturization, reduced thickness, and cost-effectiveness of parallel optical link modules.

The present invention provides a narrow strip-shaped edge-emitting micro-LED that emits light from the two end surfaces of its narrow strip-shaped structure. The micro-LED incorporates a refractive index structure designed to provide optical waveguide effects in all directions perpendicular to a light-emitting direction. This refractive index structure is formed by differences in refractive index between a semiconductor epitaxial layer and its surrounding materials. The semiconductor epitaxial layer, which grows perpendicular to the electrode surface, comprising at least one active layer, an upper cladding layer and a lower cladding layer. The active layer exhibits a refractive index higher than those of the upper and lower cladding layers, creating a refractive index contrast. An insulating layer covers at least one side surface of the semiconductor epitaxial layer, with its refractive index being lower than that of the semiconductor epitaxial layer.

The narrow strip-shaped structure has a width of less than 10 microns, and an area of the active layer is less than 1,000 square microns.

In a preferred embodiment, the refractive index structure includes one or more optical microstructures.

In a preferred embodiment, the narrow-strip-shaped edge-emitting micro-LED further comprises a waveguide layer positioned between the active layer and the upper cladding layer, as well as between the active layer and the lower cladding layer.

In a preferred embodiment, the waveguide layer is a graded-refractive-index waveguide layer.

In a preferred embodiment, the upper cladding layer or the lower cladding layer includes an optical microstructure, or both the upper cladding layer and the lower cladding layer include an optical microstructure.

In a preferred embodiment, the insulating layer is coated with a light-reflective layer.

In a preferred embodiment, the light-reflective-layer is either a metal layer with high light reflectivity or a Bragg reflector composed of multiple stacked layers of high and low dielectric materials.

In a preferred embodiment, the semiconductor epitaxial layer is composed of AlGaInN, AlGaInP, AlGaAs, InGaAsP, InGaAs or AlGaInAs.

In a preferred embodiment, one of the two end surfaces of the narrow strip-shaped structure is covered with both the insulating layer and the light reflective layer, allowing light to emit from the opposite end surface.

In a preferred embodiment, the opposite end surface from which the light emits includes an optical microstructure.

In a preferred embodiment, the light-reflective layer is either a metal layer with high light reflectivity or a Bragg reflector formed by stacking multiple layers of materials with alternating high and low dielectric constants.

In a preferred embodiment, the lower cladding layer includes a plurality of protrusions arranged in an array, with the refractive index structure formed on each protrusions. This configuration enables the micro-LED to incorporate a plurality of refractive index structures.

In a preferred embodiment, the array is arranged horizontally, vertically, or in both horizontal and vertical directions.

In a preferred embodiment, the narrow strip-shaped edge-emitting micro-LED further includes an optical lens or an optical microstructure. The optical lens or the optical microstructure is positioned on the end surface of the refractive index structure where the light exits, enabling the emitted light to be focused or directed.

### BRIEF DESCRIPTION OF THE DRAWINGS

FIG. 1 is a simplified perspective view of a conventional edge-emitting LED.

FIG. 2A is a simplified cross-sectional view of a first preferred embodiment of the present invention.

FIG. 2B is a simplified cross-sectional view of a second preferred embodiment of the present invention.

FIG. 2C is a simplified perspective view of the second preferred embodiment of the present invention.

FIG. 3A is a simplified cross-sectional view of a third preferred embodiment of the present invention.

FIG. 3B is a simplified cross-sectional view of the third preferred embodiment of the present invention, in which both an upper cladding layer and a lower cladding layer have optical microstructures.

FIG. 4 is a simplified cross-sectional view of a fourth preferred embodiment of the present invention.

FIG. 5 is a simplified cross-sectional view of a fifth preferred embodiment of the present invention.

FIG. 6A is a simplified cross-sectional view of a sixth preferred embodiment of the present invention.

FIG. 6B is a simplified cross-sectional view of a seventh preferred embodiment of the present invention.

FIG. 7 is a simplified cross-sectional view of an eighth preferred embodiment of the present invention.

FIG. 8 is a simplified cross-sectional perspective view of a ninth preferred embodiment of the present invention.

### DETAILED DESCRIPTION OF THE EMBODIMENTS

To make the above objects, features, and advantages of the present invention more apparent and easier to understand, specific embodiments of the present invention will be described in detail below in conjunction with the accompanying drawings. In the following description, numerous specific details are set forth in order to provide a thorough understanding of the invention. However, the present invention can be implemented in many other ways than those described here. Those skilled in the art can make similar improvements without departing from the connotation of the present invention. Therefore, the present invention is not limited to the specific embodiments disclosed below.

It should be noted that when an element is referred to as being “fixed to” or “disposed on” another element, it can be directly on the other element or there may be an intervening element present. Similarly, when an element is referred to as being “connected” to another element, it can be directly connected to the other element or there may be an intervening element present. The terms “vertical”, “horizontal”, “upper”, “lower”, “left”, “right” and similar expressions used in the description of the present invention are for illustrative purposes only and do not represent the only implementation manner.

In addition, the terms “first” and “second” are only used for descriptive purposes and cannot be interpreted as indicating or implying relative importance or implicitly indicating a number of indicated technical features. Therefore, features defined as “first” or “second” may explicitly or implicitly include at least one of these features. Additionally, in the context of the present invention, “multiple” and “a plurality” mean at least two, such as two, three, or more, unless explicitly and specifically stated otherwise.

In the present invention, unless otherwise expressly stipulated and limited, the first feature “on” or “beneath” the second feature may be that the first feature is in direct contact with the second feature, or the first feature is in indirect contact with the second feature through an intermediate. Moreover, the first feature is “on”, “over” and “above” the second feature may mean that the first feature is directly above or diagonally above the second feature, or simply means that a level height of the first feature is higher than that of the second feature. The first feature is “on”, “over” and “above” the second feature may mean that the first feature is directly under or diagonally under the second feature, or simply means that a level height of the first feature is less than that of the second feature.

Unless otherwise defined, all technical and scientific terms used in the description of the present invention have the same meanings as commonly understood by those skilled in the art of the present invention. The terms used in the description of the present invention are only for the purpose of describing specific embodiments and are not intended to limit the present invention. As used in this specification, the term “and/or” includes any and all combinations of one or more of the associated listed items.

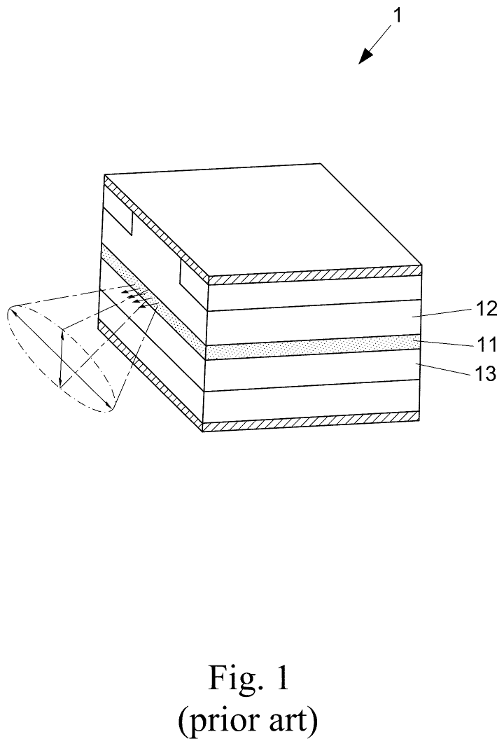

Please refer to FIG. 1, which shows a conventional edge-emitting LED 1. The structure adopts a double heterostructure, wherein the active layer 11 is sandwiched between cladding layers 12 and 13, which have a larger energy bandgap and a smaller refraction index. The upper cladding layer 12 and the lower cladding layer 13 facilitate the injection and confinement of electrons and holes within the active layer 11. This increases the probability of radiative recombination of electrons and holes in the active layer 11, resulting in light emission. Additionally, as light propagates vertically (upward and downward), most of it undergoes total internal reflection, thereby allowing light to emit primarily from the two ends of the active layer 11.

In addition, since the refractive index of the active layer 11 is greater than that of the cladding layers 12 and 13, most of the light generated by the radiation recombination of electrons and holes is confined within the active layer 11 and propagates through it. As the light in the direction perpendicular to the active layer 11 is confined, the beam divergence angle in this direction is relatively small, approximatively 30 degrees. However, on the left and right sides parallel to the active layer 11, there is no structural design to confine the light. Consequently, the radiation distribution of the light source in the direction parallel to the active layer 11 resembles a Lambertian distribution. This results in relatively large beam divergence angle of about 120 degrees in the direction parallel to the active layer 11.

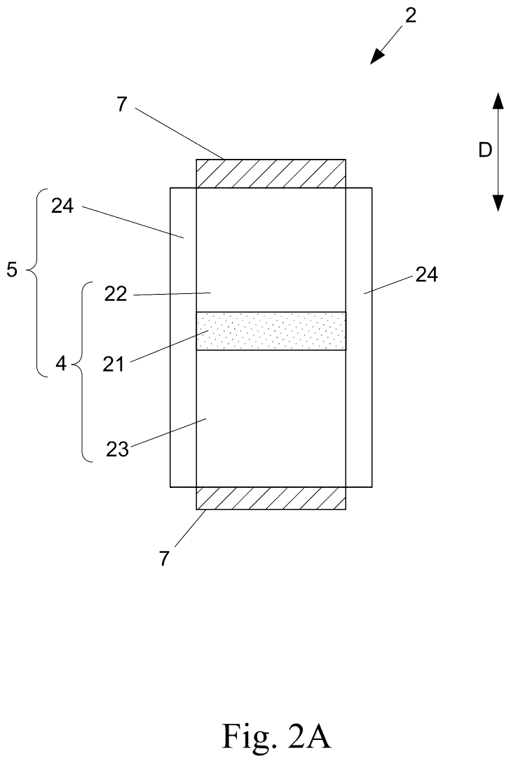

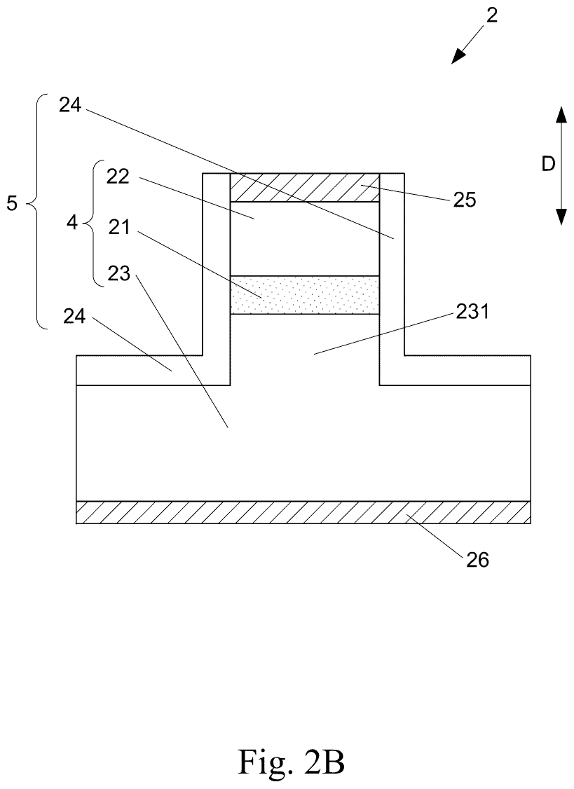

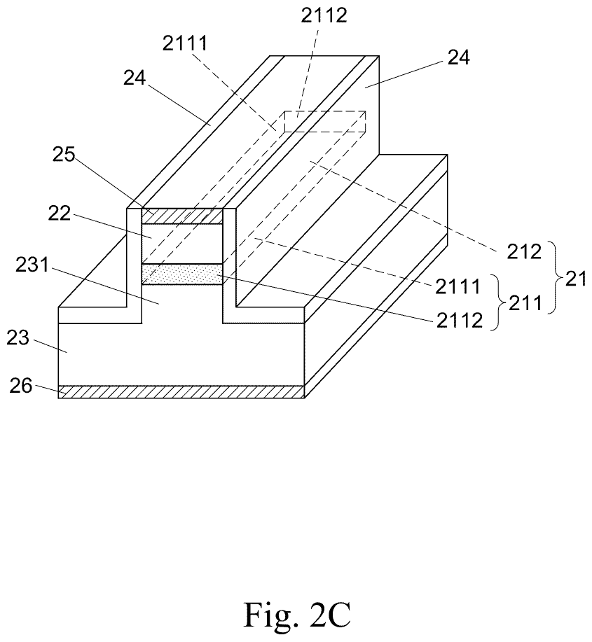

Please refer to FIG. 2A, which illustrates a simplified cross-sectional view of the first embodiment of the present invention. The invention relates to a narrow strip-shaped edge-emitting micro-LED 2 designed to emit light from both end surfaces of its narrow strip-shaped structure. The narrow strip-shaped edge-emitting micro-LED 2 includes: a refractive index structure 5 that provides optical waveguide effects in all directions perpendicular to a light-emitting direction. The refractive index structure 5 includes a semiconductor epitaxial layer 4 that grows perpendicular to an electrode surface 7, with varying refractive index across the layered structures within the semiconductor epitaxial layer 4. The semiconductor epitaxial layer 4 comprise at least one active layer 21, an upper cladding layer 22, and a lower cladding layer 23. The active layer 21 is situated between the upper cladding layer 22 and the lower cladding layer 23, with distinct refractive index differences between the active layer 11 and each of the upper and lower cladding layers. An insulating layer 24 is positioned to cover at least one of the left or right side surfaces of the semiconductor epitaxial layer 4. In a preferred embodiment, the insulating layer 24 covers at least the left and right side surfaces of the active layer 21; however, it is not limited thereto. The insulating layer 24 has a lower refractive index compared to the semiconductor epitaxial layer 4.

Please refer to FIG. 2B and FIG. 2C, which illustrate a simplified cross-sectional view and a simplified perspective view of the second embodiment of the present invention. The active layer 21 further includes a surrounding surface 211 and two corresponding upper and lower surfaces 212. The surrounding surface 211 is connected to the two surfaces 212. The surrounding surface 211 comprises two corresponding left and right side surfaces 2111, and two corresponding front and rear end surfaces 2112. The two surfaces 212 are respectively connected to the upper cladding layer 22 and the lower cladding layer 23. The two side surfaces 2111 are respectively connected to the insulating layer 24. The active layer 21 emits light energy only from the two corresponding front and rear end surfaces 2112.

In addition to the above, in this embodiment, the lower cladding layer 23 includes a protrusion 231. The active layer 21 is located on the protrusion 231, and the active layer 21 emits light energy only from the two corresponding front and rear end surfaces 2112.

In addition, the narrow strip-shaped edge-emitting micro-LED 2 further includes a first electrode layer 25 and a second electrode layer 26. The first electrode layer 25 extends along the electrode surface 7 and is connected to the upper cladding layer 22 in a direction D perpendicular to the electrode surface 7. The second electrode layer 26 is connected to the lower cladding layer 23 along the direction D. Furthermore, the insulating layer 24 covers part or all of the upper cladding layer 22, completely covering both side surfaces 2111 of the active layer 21, and partially or fully covering the lower cladding layer 23.

That is, the present invention utilizes the narrow strip-shaped refractive index structure 5 to provide the optical waveguide function and emit light from the two end surfaces 2112 of the narrow strip-shaped active layer 21. Most of light is totally reflected and confined within the refractive index structure of the optical waveguide as it travels along the four surfaces—upper, lower, left and right—thereby restricting its propagation to the long axis direction of the front and rear surfaces 2112. The refractive index structure 5 is formed by growing the semiconductor epitaxial layer in the direction D perpendicular to the active layer 21 using epitaxial growth. N-type and P-type cladding layers (22, 23) with larger energy gap are grown on the two surfaces 212 of the active layer 21, which has a smaller energy gap. The two side surfaces 2111 of the active layer 21 are connected to the insulating layer 24, forming a double heterostructure that confines light within the active layer 21 and emits light energy from the two end surfaces 2112, or alternatively from one of the two end surfaces 2112.

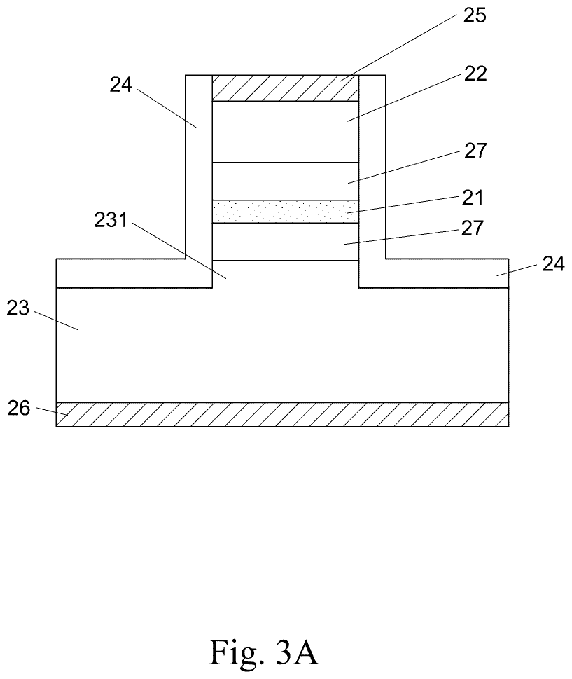

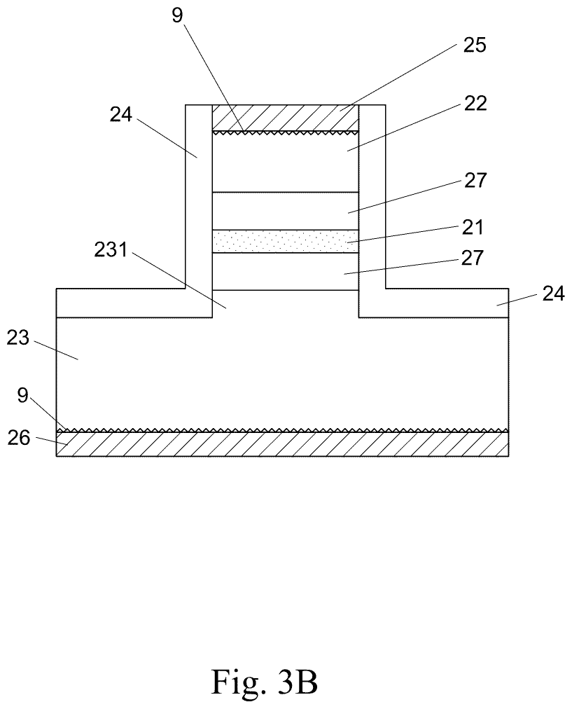

Please refer to FIG. 3A and FIG. 3B, which are simplified cross-sectional views illustrating the third preferred embodiment of the present invention. FIG. 3A shows a basic structure, while FIG. 3B depicts a structure where both the upper cladding layer and the lower cladding layer include optical microstructures. In this embodiment, in addition to the double heterostructure, a separate confinement heterostructure can also be employed. The structure includes an optical waveguide composed of an active layer 21, at least one waveguide layer 27, and two insulating layers 24. Preferably, this embodiment features an optical waveguide structure comprising five semiconductor layers: the active layer 21, two waveguide layers 27, and the two insulating layers 24. The two waveguides layers 27 are positioned respectively between the active layer 21 and the upper cladding layer 22, and between the active layer 21 and the lower cladding layer 23. This structure can confine carriers and photons in the active layer 21 and the waveguide layer 27, respectively, resulting in high radiation recombination efficiency of electrons and holes within the active layer 21. The generated photons travel and propagate within the waveguide layer 27, which has a larger energy gap and a greater thickness, minimizing reabsorption losses in the active layer 21. In addition, at least one of the upper cladding layer 22 or the lower cladding layer 23 may include an optical microstructure 9. Preferably, the optical microstructure 9 is located on the top of the upper cladding layer 22 or the bottom of the lower cladding layer 23, though it is not limited thereto. Since light is mainly confined within the active layer 21 and the waveguide layer 27, any light that escapes these layers can be redirected by the optical microstructure 9 back into the active layer 21 and the waveguide layer 27. The optical microstructure 9 thus improves transmission efficiency, reduces reabsorption losses, and further controls the path of light propagation. Furthermore, the optical microstructure 9 may also be applied to the refractive index structure 5 to enhance the overall optical performance of the device.

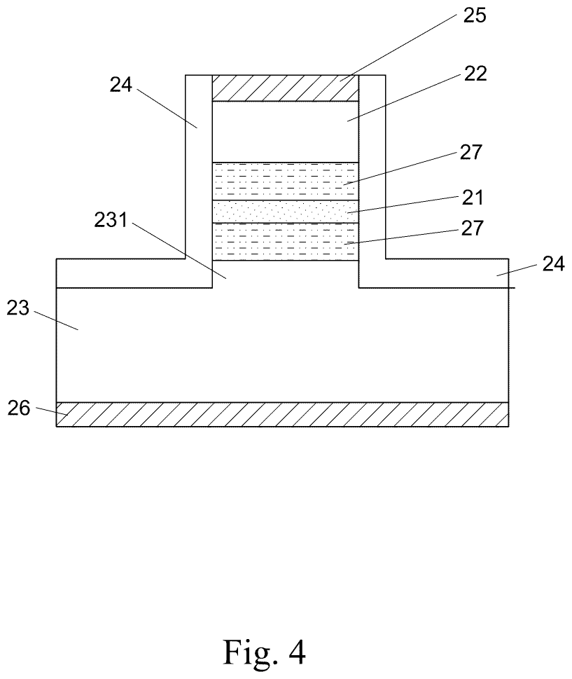

Please refer to FIG. 4, which is a simplified cross-sectional view illustrating the fourth preferred embodiment of the present invention. In addition, FIG. 4 shows another graded-index separate confinement heterostructure. Similar to the separate confinement heterostructure, this design provides separate confinement for carries and photon. The main difference in this embodiment lies in photon confinement. Instead of using a waveguide layer 27 with a fixed energy gap, a waveguide layer 27 with a graded energy gap is employed. The gradual change in the semiconductor energy gap corresponds to a change in the refractive index. By continuously varying the composition of the epitaxial layer during the growth of the semiconductor epitaxial layer, the waveguide layer 27 achieves a continuous variation in energy gap size. This results in a waveguide layer 27 with a graded refractive index, enhancing light confinement within the optical waveguide structure.

Specifically, the narrow strip-shaped structure of the narrow strip-shaped edge-emitting micro-LED, as disclosed in FIG. 2B and FIG. 2C, is fabricated by etching the upper cladding layer 22, the active layer 21 and a portion of the lower cladding layer 23 in regions outside the narrow strip to form a grain structure with a wide bottom and a narrow top, as shown in FIG. 2B and FIG. 2C. This structural design, with a wider base and a narrow top, provides the narrow strip-shaped edge-emitting micro-LED grain with enhanced stability and resistance to toppling. The main requirement of the present invention is the narrow strip-shaped edge-emitting micro-LED, particularly the light-exiting direction of the active layer 21 and the four surfaces parallel to the light-exiting direction, which relate to the optical waveguide structure formed by the refractive index differences. The narrow-strip-shaped edge-emitting micro-LED grain of the present invention can be produced by completely etching the upper cladding layer 22, the active layer 21, and the lower cladding layer 23 outside the narrow strip-shaped structure. This process forms a narrow strip-shaped edge-emitting micro-LED grain with a consistent width from top to bottom. In addition, due to etching process limitations, the two side surfaces of the narrow edge-emitting micro-LED grain may not be perfectly perpendicular to the semiconductor epitaxial layer or the electrode surface and may exhibit slightly inclinations. However, these minor deviation do not impact the waveguide characteristics, as the functionality relies on differences in refractive index.

In other words, by utilizing the narrow strip-shaped micro-LED with the optical waveguide structure, the upper, lower, left, and right surfaces of the active layer 21 are covered with a material of smaller refractive index. Consequently, the majority of the light traveling in the upward, downward, leftward, or rightward directions undergoes total internal reflection, allowing emission only through the two ends of the narrow strip-shaped edge-emitting micro-LED. This design results in a smaller light divergence angle and minimizes light loss when coupling with transmission media such as single-mode optical fibers or optical waveguides.

Since a core of a single-mode optical fiber or a single-mode optical waveguide is less than 10 microns, the strip width of the narrow strip-shaped edge-emitting micro-LED of the present invention should also be less than 10 microns. This ensures that light emitted from the end face 2112 can be effectively coupled to the single-mode optical fiber or waveguide. For high butt-coupling efficiency, the width W of the narrow strip-shaped structure should be as narrow as possible, ideally less than half of a core diameter of the single-mode optical fiber—that is, less than or equal to 5 microns.

In addition, to achieve a high modulation bandwidth and thereby support a high data rate, the modulation bandwidth of the LED can be optimized. The modulation bandwidth of the LED is determined by the carrier lifetime and the RC time constant. To improve the modulation bandwidth, the epitaxial structure may be optimized to reduce the carrier lifetime. Furthermore, the size of the LED may be reduced to decrease the capacitance, thereby reducing the RC time constant. These optimizations facilitate achieving an improved modulation bandwidth for the LED. Refer to “Bandwidth Analysis of High-Speed InGaN, Micro-LEDs by an Equivalent Circuit Model”, Z. Li et al., IEEE ELECTRON DEVICE LETTERS, VOL. 44, NO. 5, May 1, 2023, which discloses a component with 20 microns. Based on the theoretical RC value, the transmission speed of this component could reach 4 GHz. Experimental measurements yielded results of approximately 3.5 GHZ, with the component having an area of 20 microns×20 microns, equivalent to 400 square microns. If the area is enlarged by 2.5 times, the −3 dB bandwidth is estimated to decreased to 1.4 GHz, which can achieve a design goal of greater than 1 GHz. As an example, to achieve a modulation bandwidth exceeding 1 GHz, the light-emitting area of the LED should be less than 1,000 square microns. This is equivalent to a surface-emitting micro-LED size of approximately 32 microns×32 microns. When applied to the narrow strip-shaped edge-emitting micro-LED of the present invention, this corresponds to a width of 10 microns and a length of 100 microns. Furthermore, using the current wafer manufacturing process technology of the present invention, it is feasible to fabricate a narrow strip-shaped edge-emitting micro-LED with a smaller size, such as a micro-LED grain having a width of 2 microns and a length of 20 microns, or a width of 1 micron and a length of 10 microns. The light-emitting end of such a narrow micro-LED grain can be easily embedded or coupled into a very narrow optical waveguide, thereby meeting the requirements for high bandwidth density.

In addition, the P-type and N-type metal electrodes of the narrow strip-shaped edge-emitting micro-LED are formed on upper and lower surfaces and do not cover the light-exiting surface. In contrast, in a conventional surface-emitting micro-LED design, metal electrodes are typically plated on the light-exiting surface. To avoid blocking light and reducing the luminous efficiency, the metal electrodes are often only partially plated on the light-exiting surface. However, this partial plating results in higher contact resistance and uneven current distribution, which can adversely affect the performance of the LED.

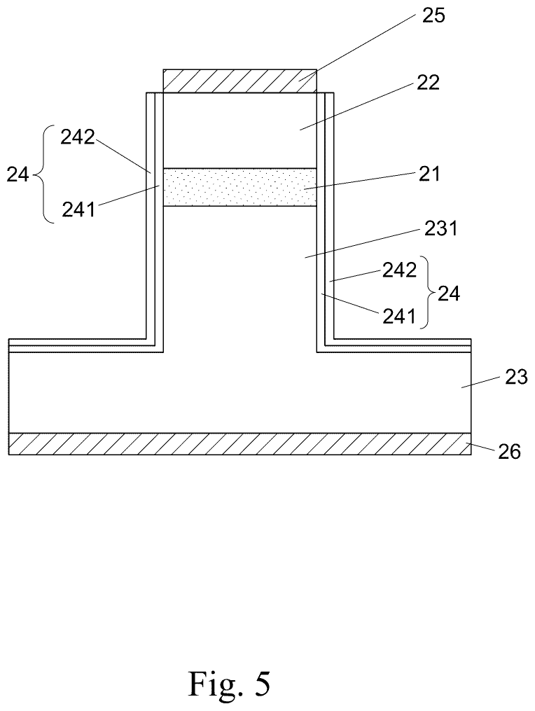

Please refer to FIG. 5, which is a simplified cross-sectional view of the fifth preferred embodiment of the present invention. In this embodiment, the insulating layer 24 includes two distinct layers: a sub-insulating layer 241 and a light reflective layer 242. The sub-insulating layer 241 is positioned near to the upper cladding layer 22, and the light reflective layer 242 covers the sub-insulating layer 241. The light reflective layer 242 can be made of a metal or a Bragg reflective layer, both of which possess high light reflectivity. This design helps to further improve light confinement and efficiency in the narrow strip-shaped edge-emitting micro-LED.

That is, in order to localize the light on the left and right sides, both sides of the narrow strip-shaped structure are covered with the sub-insulating layer 241, which is made of a dielectric or polymer material with a low refractive index and insulation properties. The refractive index difference between the compound semiconductor layer in the middle and the sub-insulating layers 241 on both sides helps confine the light to the left and right sides. Additionally, the light reflective layer 242 can be further applied to the sub-insulating layer 241. The light reflective layer 242 can be a metal layer with high light reflectivity or a distributed Bragg reflector (DBR) formed by stacking multiple layers of high and low dielectric materials. This structure improves the light confinement effect as the light propagates through the device. In this embodiment, the grain of the narrow strip-shaped edge-emitting micro-LED 2 is formed into the narrow strip-shaped structure in the direction parallel to the active layer 21. The width of this structure is related to the size of the optical fiber or optical waveguide to be coupled. The narrower the width, the easier it is to couple light to the optical fiber or the waveguide.

It should be noted that since the core diameter of a single-mode optical fiber or a single-mode optical waveguide is less than 10 microns, the strip width of the narrow-strip-shaped edge-emitting micro-LED of the present invention must also be less than 10 microns to effectively butt couple light to the single-mode optical fiber. To further improve the efficiency of butt coupling, the width of the narrow strip-shaped edge-emitting micro-LED should preferably be less than half the diameter of the core layer of the single-mode optical fiber, that is, less than or equal to 5 microns. Even more ideally, the width should be less than a quarter of the diameter of the core layer of the single-mode optical fiber, that is, less than or equal to 2 microns. This ensures that, even if there is some misalignment during butt coupling, light can still be effectively coupled into the single-mode optical fiber.

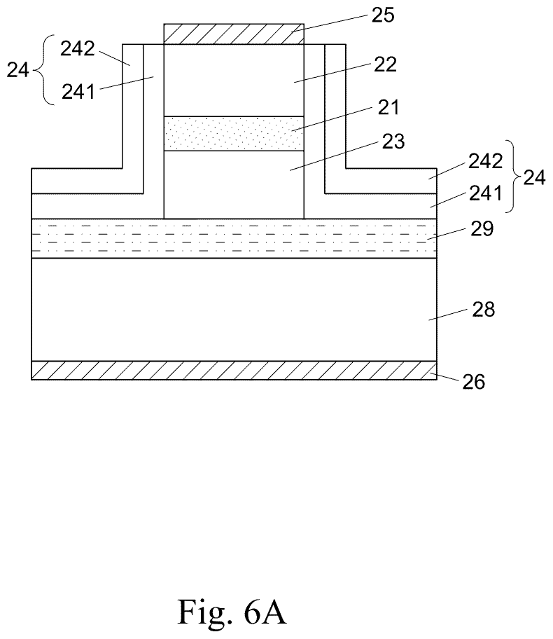

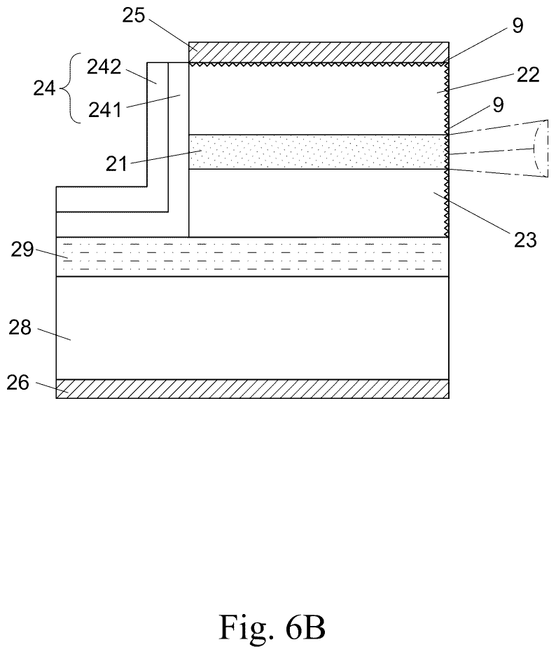

In addition, please refer to FIGS. 6A and 6B, which illustrate the sixth and seventh preferred embodiment of the present invention. FIG. 6A shows a 650 nm AlGaAs edge-emitting micro-LED structure, providing a cross-sectional view perpendicular to the light-exiting direction, while FIG. 6B presents a longitudinal cross-section view parallel to the light-exiting direction. In this embodiment, the narrow strip-shaped edge-emitting micro-LED 2 also includes a substrate 28 and a reflective layer 29. The sub-insulating layer 241 is a protective layer with a low refractive index, while the light reflective layer 242 is a high light reflectivity layer. The substrate 28 is connected to the second electrode layer 26 in the direction D, and the reflective layer 29 is connected to the substrate 28 in the direction D. The lower cladding layer 23 has a protrusion 231 which extents outward from the reflective layer 29.

To illustrate with a more specific embodiment, as shown in FIG. 6A, the epitaxial structure of the edge-emitting micro-LED is composed of the following layers from bottom to top: second electrode layer 26, the substrate 28 of N-type GaAs, the reflective layer 29 of N-type AlGaAs/AlAs, the lower cladding layer 23 of N-type AlInGaP, the active layer 21 of InGaP, the upper cladding layer 22 of P-type AlGaInP, and the first electrode layer 25 of P-type high reflectivity metal. The reflective layer 29 is a distributed Bragg reflective (DBR) layer, designed to enhance light confinement and device efficiency.

In addition, the two sides of the epitaxial structure are covered with the insulating layer 24. The insulating layer 24 consists of a sub-insulating layer 241 and a light reflective layer 242, The sub-insulating layer 241 is a protective layer with low refractive index, such as silicon dioxide (SiO₂). The sub-insulating layer 241 is covered by a light reflective layer 242, which is made of either a metal layer with high light reflectivity or a distributed Bragg reflector (DBR). The DBR is formed by stacking multiple layers of high and low dielectric materials, and it serves to enhance the light confinement within the optical waveguide structure. The light reflective layer 242 directs and reflects the emitted light back toward the ends of the narrow strip-shaped micro-LED, thereby improving light efficiency and ensuring that the light is effectively emitted from the ends rather than escaping through the sides. The optical waveguide structure is completed by surrounding the active layer 21 with the upper cladding layer 22, lower cladding layer 23, and the insulating layer 24. The refractive index difference between these layers confines most of the light generated in the active layer 21, causing it to be totally internally reflected and emitted from the two ends of the narrow strip-shaped structure. The first electrode layer 25 and the reflective layer 242 placed on the outer surfaces of the cladding and insulating layers help to further enhance the light confinement and directivity, improving the overall efficiency of the narrow strip-shaped edge-emitting micro-LED.

In addition, as shown in the cross-sectional view of FIG. 6B, one end of the narrow strip-shaped edge-emitting micro-LED 2 can be covered with the insulating layer 24. This layer includes the sub-insulating layer 241 made of silicon dioxide and a light reflective layer 242 with high light reflectivity. By covering one end with these layers, the emitted light is effectively guided to the opposite end of the edge-emitting micro-LED, ensuring that it is emitted only from that specific end. Therefore, a narrow strip-shaped edge-emitting micro-LED 2 with a smaller beam divergence angle and higher light radiation intensity can be obtained.

That is, the insulating layer 24 further covers one of the second end surfaces 2112 in the same direction as the upper cladding layer 22, active layer 21, and lower cladding layer 23. As a result, the active layer 21 emits the light energy only from the other second end surface 2112, ensuring that the emitted light is directed efficiently. This design enables the narrow strip-shaped edge-emitting micro-LED 2 to achieve a small beam divergence angle and higher light radiation intensity, improving the overall performance of the device.

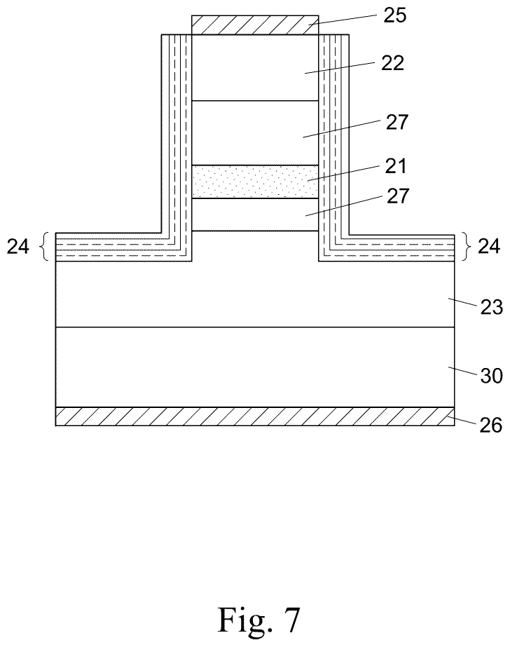

Please refer to FIG. 7, which is a simplified cross-sectional view of the eighth preferred embodiment of the present invention. The micro-LED further includes a silicon substrate 30, which is connected to the second electrode layer 26 in the direction D. The lower cladding layer 23 is connected to the silicon substrate 30 in the direction D, and the insulating layer 24 is a distributed Bragg reflector formed from multi-layer films. Additionally, the active layer 21 is a multiple quantum well layer.

This embodiment shown in FIG. 7 describes an edge-emitting micro-LED suitable for blue light according to the present invention. The structure begins with a silicon substrate 30, on which a series of layers are sequentially grown or bonded. These layers include: the lower cladding layer 23 of N-type AlGaN, the waveguide layer 27 of N-type GaN, the active layer 21 of InGaN or GaN multiple quantum well layer, the other waveguide layer 27 of P-type GaN, and the upper cladding layer 22 of P-type AlGaN. These layers together form a separate confinement heterostructure, and the insulating layer 24 is applied to both sides. The insulating layer 24 is a distributed Bragg reflective layer, created from alternating layers of silicon dioxide (SiO2) and titanium dioxide (TiO2) (SiO2/TiO2). This multi-layer structure serves to further confine the light within the device. Due to the waveguide structure formed by the separate confinement heterostructure and the distributed Bragg reflective layer, light is confined both vertically and horizontally, ensuring that the narrow strip-shaped edge-emitting LED 2 emits light with a small beam divergence angle and high light radiation intensity.

In addition to the narrow strip-shaped edge-emitting micro-LED composed of AlGaInP, which can produce light in the red to yellow-green spectrum with wavelength ranging from 560 nm to 650 nm, and those composed of AlGaInN, which produce blue to green light, the present invention is also applicable to infrared narrow strip-shaped edge-emitting micro-LEDs. These infrared LEDs can be fabricated using materials such as AlGaAs, InGaAs, InGaAsP, AlGaInAs, and other similar semiconductor compounds.

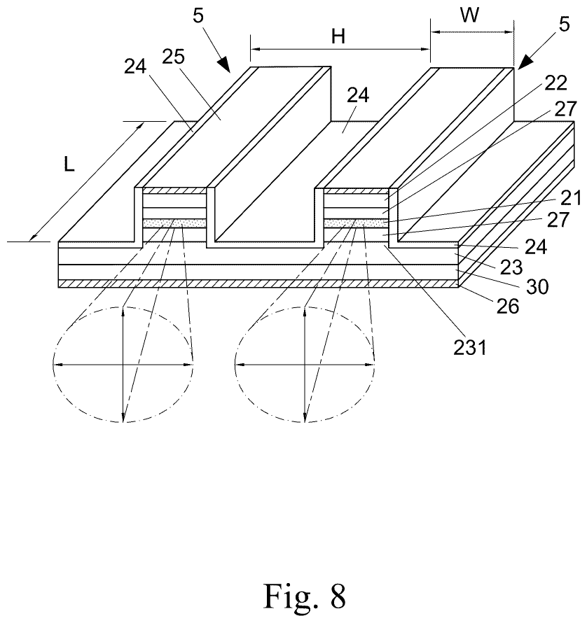

Please refer to FIG. 8, which illustrates a simplified cross-sectional perspective view of the ninth preferred embodiment of the present invention. In this embodiment, the lower cladding layer 23 includes a plurality of protrusions 231 arranged in an array. The array can be configured in a horizontal arrangement, a vertical arrangement, or a combination of both horizontal and vertical arrangements. A refractive index structure 5 is formed on each of the protrusions 231, resulting in the narrow strip-shaped edge-emitting micro-LED 2 comprising a plurality of refractive index structures 5. Each refractive index structure 5 is designed with a width W, while the micro-LED 2 itself has an overall length L, and a pitch H between two adjacent strip portions 7.

That is, this embodiment represents an edge-emitting micro-LED array. The protrusions 231 are arranged in an array, which can be configured horizontally, vertically, or in a combination of both horizontal and vertical arrangements. In this embodiment, the width W of the narrow strip-shaped structure is 2 microns, the length Lis 10 microns, and the pitch H is 10 microns. Due to the small beam divergence angle of this design, when the light-exiting surface of the narrow-strip-shaped edge-emitting micro-LED 2 is positioned very close to and aligned with the end surface of a single-mode optical fiber or waveguide, most of the light emitted from the narrow strip-shaped edge-emitting micro-LED 2 can be coupled into the optical fiber or waveguide. Additionally, the light-exiting surface of the narrow-strip-shaped edge-emitting micro-LED 2 may include an optical lens or an optical microstructure (not shown in the figure). These elements help to focus or guide the emitted light, improving the positioning and alignment with the end face of the single-mode optical fiber or waveguide, thereby enhancing coupling efficiency.

In addition, it is worth mentioning that the design of the narrow strip-shaped edge-emitting micro-LED array of the present invention allows for a total width of 1 mm, accommodating up to 100 refractive index structures 5 within the array for emitting light energy. Assuming that each narrow strip-shaped micro-LED 2 achieves a transmission rate of 10 Gbps, the entire array can deliver an impressive high bandwidth density of 1 Tbps/mm.

If the design reduces the width W of each narrow strip-shaped edge-emitting micro-LED 2 to 1 micron and the pitch H between two adjacent of the narrow strip-shaped edge-emitting micro-LEDs to 5 microns, a 1 mm-wide array can accommodate up to 200 narrow strip-shaped edge-emitting micro-LEDs 2. Additionally,, the width of the corresponding coupled waveguide would be approximately 3 microns, which is three times larger than that of the narrow strip-shaped edge-emitting micro-LED 2, resulting in high butt coupling efficiency. Furthermore, if the data rate of each edge-emitting micro-LED 2 is increased to 15 Gbps, the array can achieve an exceptional high bandwidth density of 3 Tbps/mm.

Since the width W of the narrow strip-shaped edge-emitting micro-LED 2 of the present invention is less than 10 microns, it ensures high coupling efficiency when butt coupled to a single-mode optical fiber or waveguide. Moreover, even in short-distance optical links, the light-emitting end of the narrow-strip-shaped edge-emitting micro-LED 2 can be embedded and coupled to the optical waveguide. This approach not only simplifies the optical coupling process but also enables the effective coupling of most of the emitted light into the optical waveguide.

To sum up, the present invention utilizes a narrow strip-shaped edge-emitting micro-LED that incorporates low refractive index or insulating materials to form an optical waveguide structure surrounding the upper, lower, left and right sides of the active layer. This design effectively confines the light source to transmit in a single direction while minimizing absorption loss. As a result, the invention achieves a micro-LED with a small beam divergence angle and higher light radiation intensity.

In addition, the size of each narrow strip-shaped edge-emitting micro-LED in the present invention is further optimized and limited. A narrower width facilitates easier light coupling light into the optical fiber or optical waveguide, simplifying optical fiber alignment between the light source and the target optical fiber, thereby reducing light loss during coupling. Consequently, the invention offers significant advantages in terms of miniaturization, thinness and cost reduction for parallel optical link modules.

The detailed description provided above outlines specific embodiments of the present invention. However, these embodiments are not intended to limit the scope of the invention. Any equivalent implementations or modifications that do not deviate from the technical spirit of the invention are to be considered within the scope of the claims of the present application.

What is claimed is:

1. A narrow strip-shaped edge-emitting micro-LED that emits light from two end surfaces of a narrow strip-shaped structure, the micro-LED comprising:
a refractive index structure that provides optical waveguide effects, the refractive index structure being formed by a difference in refractive index between a semiconductor epitaxial layer which grows perpendicular to an electrode surface, the semiconductor epitaxial layer comprising at least one active layer, an upper cladding layer and a lower cladding layer, the active layer having refractive index difference with the upper cladding layer and the lower cladding layer, respectively, and a refractive index of the active layer being higher than those of the upper and lower cladding layers, and an insulating layer covering at least one side surface of the semiconductor epitaxial layer, and a refractive index of the insulating layer being smaller than that of the semiconductor epitaxial layer, and the narrow strip-shaped structure having a width of less than 10 microns, and an area of the active layer being less than 1,000 square microns.

2. The narrow strip-shaped edge-emitting micro-LED of claim 1, wherein the refractive index structure has one or more optical microstructures.

3. The narrow strip-shaped edge-emitting micro-LED of claim 1, wherein the narrow strip-shaped edge-emitting micro-LED further comprises a waveguide layer located between the active layer and the upper cladding layer and between the active layer and the lower cladding layer.

4. The narrow strip-shaped edge-emitting micro-LED of claim 3, wherein the waveguide layer is a graded refractive index waveguide layer.

5. The narrow strip-shaped edge-emitting micro-LED of claim 3, wherein the upper cladding layer or the lower cladding layer has an optical microstructure, or each of the upper cladding layer and the lower cladding layer has an optical microstructure.

6. The narrow strip-shaped edge-emitting micro-LED of claim 1, wherein the insulating layer is covered with a light reflective layer.

7. The narrow strip-shaped edge-emitting micro-LED of claim 6, wherein the light reflective layer is a metal layer with high light reflectivity, or a Bragg reflector formed by stacking multiple layers of high and low dielectric materials.

8. The narrow strip-shaped edge-emitting micro-LED of claim 1, wherein the semiconductor epitaxial layer is made of AlGaInN, AlGaInP, AlGaAs, InGaAsP, InGaAs or AlGaInAs.

9. The narrow strip-shaped edge-emitting micro-LED of claim 1, wherein one of the two end surfaces of the narrow strip-shaped structure is covered with the insulating layer and a light reflective layer to allow the light to emit from the other end surface.

10. The narrow strip-shaped edge-emitting micro-LED of claim 9, wherein the other end surface from which the light emits has an optical microstructure.

11. The narrow strip-shaped edge-emitting micro-LED of claim 9, wherein the light reflective layer is a metal layer with high light reflectivity, or a Bragg reflector formed by stacking multiple layers of high and low dielectric materials.

12. The narrow strip-shaped edge-emitting micro-LED of claim 1, wherein the lower cladding layer comprises a plurality of protrusions, and the protrusions are arranged in an array, and the refractive index structure is formed on each of the protrusions, so that the micro-LED has a plurality of the refractive index structures.

13. The narrow strip-shaped edge-emitting micro-LED of claim 12, wherein the array is horizontally, vertically, or both horizontally and vertically arranged.

14. The narrow strip-shaped edge-emitting micro-LED of claim 12, wherein the narrow strip-shaped edge-emitting micro-LED further comprises an optical lens or an optical microstructure, and the optical lens or the optical microstructure is disposed on the end surface of the refractive index structure that light exits.
